(19) United States
(12) Patent Application Publication
(10) Pub. No.: US 2025/0044694 A1
(43) Pub. Date: Feb. 6, 2025

(54) METHODS OF MANUFACTURING MULTI-LAYERED PHOTORESIST FILMS AND INTEGRATED CIRCUIT DEVICES

(71) Applicant: Samsung Electronics Co., Ltd., Suwon-si (KR)

(72) Inventor: Sungkun Kang, Suwon-si (KR)

(21) Appl. No.: 18/606,108

(22) Filed: Mar. 15, 2024

(30) Foreign Application Priority Data
Aug. 4, 2023 (KR) 10-2023-0102287

(51) Int. Cl. G03F 7/09; G03F 7/095

(52) U.S. Cl. CPC G03F 7/094; G03F 7/095

(57) ABSTRACT

Photoresist films are described such as those that include a first photoresist layer including a first photosensitive polymer and a second photoresist layer that includes a second photosensitive polymer, the second photoresist layer being disposed at two or more different positions in a direction perpendicular to a surface of the first photoresist layer, and wherein the second photosensitive polymer is hydrogen bonded, covalently bonded, or ionically bonded to the first photosensitive polymer. Also described are methods of manufacturing an integrated circuit device using a photoresist film.

### CROSS-REFERENCE TO RELATED APPLICATION

This application claims priority under 35 U.S.C. § 119 to Korean Patent Application No. 10-2023-0102287, filed on Aug. 4, 2023, in the Korean Intellectual Property Office, the disclosure of which is incorporated by reference herein in its entirety.

The present invention relates to methods of manufacturing a multi-layered photoresist film and to methods of manufacturing an integrated circuit device, and more particularly, to methods of manufacturing a multi-layered photoresist film by using a layer-by-layer self-assembly (LBL self-assembly).

### BACKGROUND

Recently, due to the development of electronic technology, down-scaling of semiconductor devices has rapidly progressed. Accordingly, a photolithography process that is advantageous for implementing a fine pattern is desired. In particular, there is a need to develop technology that increases light sensitivity and improves dissolution contrast of a developing solution between exposed and unexposed regions of a photoresist film in a photolithography process for manufacturing integrated circuit devices.

### SUMMARY

The inventive concept provides methods of manufacturing a multi-layered photoresist film and/or an integrated circuit device whereby light sensitivity and/or contrast are improved in a photolithography process for manufacturing the integrated circuit device.

The problems to be solved by the technical spirit of the inventive concept are not limited to the problems mentioned above, and other problems not mentioned will be clearly understood by those skilled in the art from the following description.

According to an aspect of the inventive concept, there is provided a photoresist film including a first photoresist layer including a first photosensitive polymer and a second photoresist layer including a second photosensitive polymer, wherein the second photosensitive polymer forms a hydrogen bond, a covalent bond, or an ionic bond with the first photosensitive polymer.

The second photosensitive polymer may be hydrogen bonded, covalently bonded, or ionically bonded to the first photosensitive polymer. In the photoresist film, the second photoresist layer may be disposed at different levels in a direction perpendicular to the first photoresist layer. In some embodiments, in the photoresist film, the second photoresist layer is disposed at two or more different positions in a direction perpendicular to a surface of the first photoresist layer (e.g., a surface of the first photoresist layer that extends in the horizontal direction or x-direction).

According to an aspect of the inventive concept, there is provided a photoresist film including a first photoresist layer including a first photosensitive polymer and a second photoresist layer including a second photosensitive polymer and that is disposed at different levels in a direction perpendicular to the first photoresist layer, wherein the first photoresist layer has a different chemical composition than the second photoresist layer.

According to an aspect of the inventive concept, there is provided a method of manufacturing an integrated circuit device, the method includes providing a substrate including a feature layer and forming a photoresist film on the feature layer, wherein the forming of the photoresist film includes forming a first photoresist layer by coating a first photoresist composition including a first photosensitive polymer on the feature layer, forming a second photoresist layer by coating a second photoresist composition including a second photosensitive polymer on the first photoresist layer, and repeating the forming of the first photoresist layer and the forming of the second photoresist layer until a target thickness of the photoresist film is reached, wherein, in forming the second photoresist layer, the second photosensitive polymer forms a hydrogen bond, a covalently bond, or an ionic bond with the first photosensitive polymer.

### BRIEF DESCRIPTION OF THE DRAWINGS

Embodiments will be more clearly understood from the following detailed description taken in conjunction with the accompanying drawings in which:

FIG. 1 is a perspective view illustrating aspects of a structure of a photoresist film according to some embodiments;

FIG. 2 is an exemplary flow chart for a method of manufacturing a photoresist film according to some embodiments;

FIGS. 3A and 3B are cross-sectional views illustrating aspects of a method of manufacturing a photoresist film according to some embodiments;

FIG. 4 is an exemplary flow chart for a method of manufacturing an integrated circuit device according to some embodiments; and

FIGS. 5A to 5D are cross-sectional views illustrating aspects of a method of manufacturing an integrated circuit device according to some embodiments.

### DETAILED DESCRIPTION OF THE EMBODIMENTS

Hereinafter, embodiments of the inventive concepts are described in detail with reference to the accompanying drawings. Like reference numerals are used for the same components in the drawings, and duplicate descriptions thereof are omitted.

Within the specification, if a chemical bond is not drawn at a position where a chemical bond should be drawn in a chemical formula, it may mean that a hydrogen atom is bonded at that position, unless otherwise defined.

A first photoresist composition according to some embodiments according to the technical spirit of the present invention may include a first photosensitive polymer, a photoacid generator (PAG), and a first solvent.

In example embodiments, the first photosensitive polymer may include a first repeating unit, and the first repeating unit may include the structure of Formula 1.

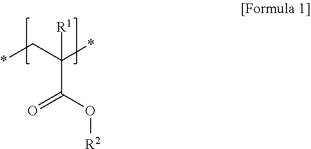

In Formula 1, R¹ represents a hydrogen atom or a methyl group, and R² represents an acid labile protecting group (also referred to herein interchangeably as an acid-decomposable protecting group), and * is a binding site.

In example embodiments, the acid labile protecting group included in a first photosensitive polymer may be selected from a substituted or unsubstituted t-butyl group and a substituted or unsubstituted tertiary alicyclic group having 3 to 30 carbon atoms.

The term “substituted” as used herein, unless otherwise defined, refers to at least one substituent, for example, a halogen atom (e.g., an F atom, a Cl atom, a Br atom, or an I atom), hydroxyl, amino, thiol, carboxyl, carboxylate, ester, amide, nitrile, sulfide, disulfide, nitro, alkyl having 1 to 20 carbon atoms, cycloalkyl having 1 to 20 carbon atoms, alkenyl having 2 to 20 carbon atoms, alkoxy having 1 to 20 carbon atoms, alkenoxy having 2 to 20 carbon atoms, aryl having 6 to 30 carbon atoms, aryloxy having 6 to 30 carbon atoms, alkylaryl having 7 to 30 carbon atoms, or alkylaryloxy group having 7 to 30 carbon atoms.

In example embodiments, an acid labile protecting group included in the first photosensitive polymer may have an unsubstituted structure. For example, the acid labile protecting group may include an unsubstituted t-butyl group or an unsubstituted tertiary alicyclic group having 3 to 30 carbon atoms.

In example embodiments, the acid labile protecting group included in the first photosensitive polymer may have a structure substituted with a first substituent. For example, the acid labile protecting group may include a t-butyl group substituted with the first substituent, or a tertiary alicyclic group having 3 to 30 carbon atoms substituted with the first substituent. The first substituent may include an alkyl group having 1 to 10 carbon atoms, an alkoxy group having 1 to 10 carbon atoms, a halogen atom, a halogenated alkyl group having 1 to 10 carbon atoms, a hydroxyl group, an unsubstituted aryl group having 6 to 30 carbon atoms, or an aryl group having 6 to 30 carbon atoms in which some of the carbon atoms constituting the first substituent are substituted with a halogen atom or a heteroatom containing group. A halogen atom that may be included in the first substituent may be selected from a fluorine (F) atom, chlorine (Cl) atom, bromine (Br) atom, and iodine (I) atom. The halogenated alkyl group may include at least one halogen atom selected from F atom, Cl atom, Br atom, and I atom. The heteroatom may be an oxygen atom, a sulfur atom, or a nitrogen atom. For example, the heteroatom containing group may include —O—, —C(═O)—O—, —O—C(═O)—, —C(═O)—, —O—C(═O)—O—, —C(═O)—NH—, —NH—, —S—, —S(═O)₂—, or —S(═O)₂—O—.

In example embodiments, the acid labile protecting group (e.g., acid-decomposable protecting group) included in the first photosensitive polymer may include a straight-chain, branched, or cyclic alkyl group having 1 to 6 carbon atoms, a vinyloxyethyl group, a tetrahydropyranyl group, a tetrafuranyl group, or a trifuranyl group, a trialkylsilyl group, isonobornyl, 2-methyl-2-adamantyl, 2-ethyl-2-adamantyl, 3-tetrahydrofuranyl, 3-oxocyclohexyl, γ-butyllactone-3-yl, mevalonic lactone, γ-butyrolactone-2-yl, 3-methyl-γ-butyrolactone-3-yl, 2-tetrahydropyranyl, 2-tetrahydrofuranyl, 2,3-propylenecarbonate-1-yl, 1-methoxyethyl, 1-ethoxyethyl, 1-(2-methoxyethoxy)ethyl, 1-(2-acetoxyethoxy)ethyl, t-butoxycarbonylmethyl, methoxymethyl, ethoxymethyl, trimethoxysilyl, triethoxysilyl, a methoxyethyl group, an ethoxyethyl group, an n-propoxyethyl group, an isopropoxyethyl group, a n-butoxyethyl group, an isobutoxyethyl group, a tert-butoxyethyl group, a cyclohexyloxyethyl group, a methoxypropyl group, an ethoxypropyl group, a 1-methoxy-1-methyl-ethyl group, a 1-ethoxy-1-methylethyl group, a tert-butoxycarbonyl (t-BOC), or a tert-butoxycarbonylmethyl group. The straight-chain or branched alkyl group may include a methyl group, an ethyl group, a propyl group, an isopropyl group, a n-butyl group, an isobutyl group, a tert-butyl group, a pentyl group, an isopentyl group, a neopentyl group, etc. but is not limited thereto. In addition, the cyclic alkyl group may include a cyclopentyl group, a cyclohexyl group, etc., but is not limited thereto.

In example embodiments, the first photosensitive polymer may include a 2A repeating unit. The 2A repeating unit may be configured for layer by layer self-assembly. The 2A repeating unit may include a structure and/or moiety (e.g., a functional group) for hydrogen bonding, covalent bonding, or ionic bonding such as for hydrogen bonding, covalent bonding, or ionic bonding with a 2B repeating unit. In example embodiments, the 2A repeating unit may include a functional group including oxygen (O), a functional group including fluorine (F), a functional group including nitrogen (N), or any combination thereof to form a hydrogen bond. In some embodiments, the 2A repeating unit may include a functional group including oxygen (O), a functional group including fluorine (F), a functional group including nitrogen (N), or any combination thereof to form a hydrogen bond. In some embodiments, the oxygen included in an oxygen-including functional group, the fluorine included in a fluorine-including functional group, and the nitrogen included in a nitrogen-including functional group of the 2A repeating unit may have at least one non-shared electron pair.

For example, the 2A repeating unit may include a carboxyl group, an ethylene imine group, a 4-vinylpyridine group, an ethylene oxide group, a propylene oxide group, a vinylpyrrolidone group, a 2-ethyl-2-oxazoline group, or any combination thereof. For example, the 2A repeating unit may include polycarboxylic acid, polyacrylic acid, polyethyleneimine, poly(4-vinylpyridine), poly(ethylene oxide), poly(propylene oxide), polyvinylpyrrolidone, poly(2-ethyl-2-oxazoline), or any combination thereof.

In addition, in example embodiments, the 2A repeating unit may include a functional group for forming a covalent bond. In example embodiments, the 2A repeating unit may include a functional group including a metal element or a non-metal element for forming an ionic bond.

In example embodiments, the 2A repeating unit may include a structure selected from Formula 2-1, Formula 2-2, Formula 2-3, Formula 2-4, Formula 2-5, Formula 2-6, Formula 2-7, or any combination thereof, but is not limited thereto. The 2A repeating unit may include a structure selected from Formula 2-1, Formula 2-2, Formula 2-3, Formula 2-4, Formula 2-5, Formula 2-6, and Formula 2-7, or any combination thereof, but is not limited thereto.

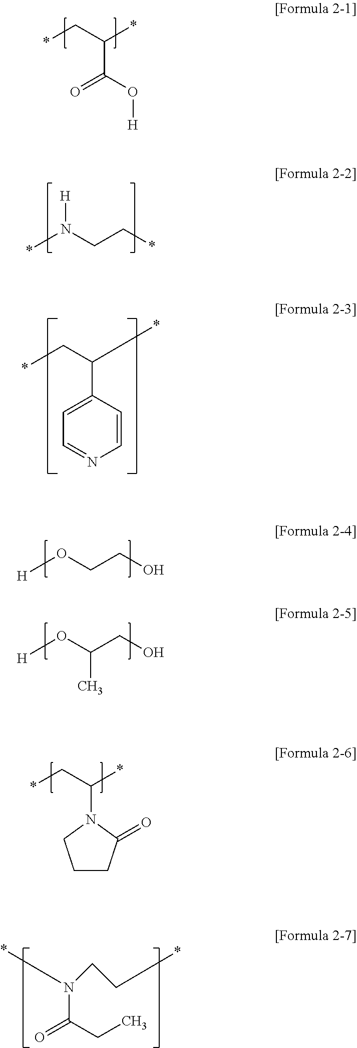

In Formula 2-1, Formula 2-2, Formula 2-3, Formula 2-4, Formula 2-5, Formula 2-6, and Formula 2-7, * is a binding site.

In example embodiments, the first photosensitive polymer may include a first repeating unit and a 2A repeating unit. In example embodiments, the first photosensitive polymer may include a structure such as Formula 1 but is not limited thereto. For example, the order of the first repeating unit and the 2A repeating unit is not limited to the order of the first repeating unit and the 2A repeating unit as in Structural Formula 1, and may be arranged in the order of the 2A repeating unit and the first repeating unit. In addition, a combination of the first repeating unit and the 2A repeating unit is not limited to the combination of the first repeating unit and the 2A repeating unit as in Structural Formula 1, and the first repeating unit and the 2A repeating unit may be arranged in various combinations, such as the first repeating unit, the first repeating unit, and the 2A repeating unit.

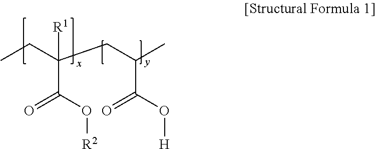

In Structural Formula 1, x may be configured such that the total weight of the first repeating unit relative to the first photosensitive polymer is about 90 wt % or more, and y may be configured such that the total weight of the 2A repeating unit relative to the first photosensitive polymer is about 10 wt % or less. In some embodiments, a first photosensitive polymer comprises a first repeating unit in an amount of about 90% or more by weight of the first photosensitive polymer, and a 2A repeating unit in an amount of about 10% or less by weight of the first photosensitive polymer.

In example embodiments, the first photosensitive polymer may further include a third repeating unit. The third repeating unit may be decomposed by an action of acid to generate phenolic acid or a BrØnsted acid corresponding to the phenolic acid. In example embodiments, the third repeating unit may include a structure obtained from hydroxystyrene or a derivative thereof. The hydroxystyrene derivative may include derivatives in which a hydrogen atom at an a position of hydroxystyrene is substituted with a C1-C5 alkyl group or a C1-C5 halogenated alkyl group and derivatives thereof. In example embodiments, the third repeating unit may include a structure obtained from methoxystyrene or a derivative thereof.

In example embodiments, the third repeating unit may include a structure of Formula 3:

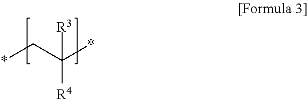

In Formula 3, R³ represents a hydrogen atom or a methyl group, R⁴ represents a C6-C30 aryl group including at least one hydroxy group or at least one methoxy group, and * indicates a binding site.

In example embodiments, R⁴ may include any one selected from a phenyl group, a naphthyl group, and an anthracenyl group, each including at least one hydroxy group or at least one methoxy group. In example embodiments, R⁴ may further include an acid labile protecting group (e.g., an acid-decomposable protecting group).

In example embodiments, R⁴ in Formula 3 may be selected from the following structures, but is not limited thereto. In the structures below, “*” indicates a binding site.

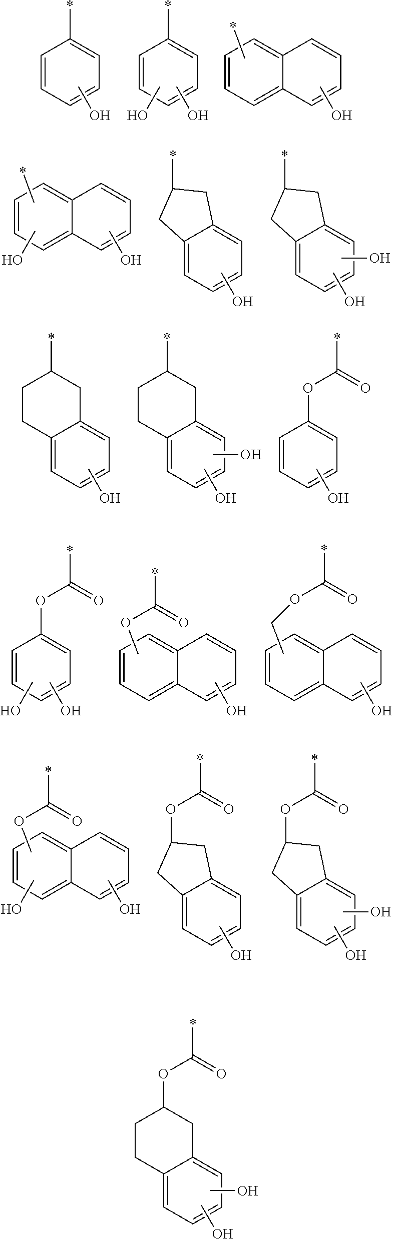

In example embodiments, the first photosensitive polymer may include a first repeating unit, a 2A repeating unit, and a third repeating unit. In example embodiments, the first photosensitive polymer may include a structure such as Structural Formula 2, but is not limited thereto. For example, the order of the first repeating unit, the 2A repeating unit, and the third repeating unit is not limited to the order of the first repeating unit, the third repeating unit, and the 2A repeating unit as in Structural Formula 2, and may be arranged in various orders. In addition, a combination of the first repeating unit, the 2A repeating unit, and the third repeating unit is not limited to the combination of the first repeating unit, the third repeating unit and the 2A repeating unit as in Structural Formula 2, and the first repeating unit, the 2A repeating unit, and the third repeating unit may be arranged in various combinations, such as the first repeating unit, the third repeating unit, and the 2A repeating unit.

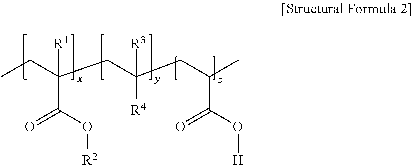

In Structural Formula 2, x+y may be configured so that a total weight of the first repeating unit and the third repeating unit relative to the weight of the first photosensitive polymer is about 90 wt % or more, and z may be configured so that a weight of the 2A repeating unit relative to the weight of the first photosensitive polymer is about 10 wt % or less. In some embodiments, a first photosensitive polymer comprises a first repeating unit and a third repeating unit, together, in an amount of about 90% or more by weight of the first photosensitive polymer, and a 2A repeating unit in an amount of about 10% or less by weight of the first photosensitive polymer.

In example embodiments, the first photosensitive polymer may further include a fourth repeating unit. In example embodiments, the first photosensitive polymer and/or the fourth repeating unit may include a material that generates an acid when the material is exposed to a light selected from a KrF excimer laser (248 nm), an ArF excimer laser (193 nm), an F2 excimer laser (157 nm), and an EUV laser (13.5 nm). In some embodiments, the first photosensitive polymer and/or the fourth repeating unit may include a material that generates a relatively strong acid with a pKa (acid dissociation constant) of about −20 to less than about 1 when exposed to light.

In some example embodiments, the fourth repeating unit may include a photodegradable base, also referred to herein as a photo-decomposable base. In some embodiments, the photodegradable base may include a compound and/or moiety that generates an acid upon exposure to light and may neutralize an acid before exposure to light. In some embodiments, when a photodegradable base is decomposed by exposure, e.g., is photo-decomposable, it may lose its ability to trap an acid. In some embodiments, when a partial region of a photoresist film formed from a first photoresist composition including a fourth repeating unit that comprises a photo-decomposable base is exposed to light, in the exposed region of the photoresist film, the photo-decomposable base loses alkalinity, and in an unexposed region of the photoresist film, the photo-decomposable base traps an acid, thereby preventing problems caused by the acid generated in the exposed region of the photoresist film diffusing into the unexposed region of the photoresist film.

In example embodiments, the fourth repeating unit may include a structure of Formula 4-1.

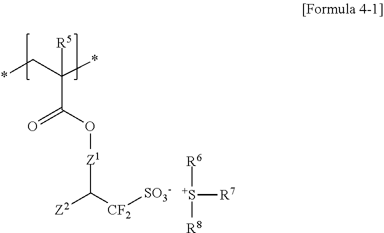

In Formula 4-1, R⁵ is hydrogen or a methyl group; R⁶, R⁷ or R⁸ each, independently may include —C═O (a carbonyl group), —O—C═O (an ester group), —O— (an ether group), a C1 to C12 straight-chain alkyl group (i.e., a straight-chain alkyl group having 1 to 12 carbon atoms), a C1 to C12 branched alkyl group, a C2 to C12 alkenyl group, a C2 to C12 alkynyl group, a C3 to C12 cycloalkyl group, a C6 to C12 aryl group, a C3 to C12 allyl group, a C1 to C12 alkoxy group, a C6 to C12 aryloxy group, a C7 to C20 aralkyl group, a mercaptophenyl group, or any combination thereof, but is not limited thereto; Z¹ may include a single bond (—), —C(═O)—O—, —O—, —O—C(═O)—, a substituted or unsubstituted C1 to C12 alkylene group, or a C6 to C12 substituted or unsubstituted cycloalkylene group, but is not limited thereto; Z² may include hydrogen or trifluoromethyl, but is not limited thereto. In some embodiments, in Formula 4-1, R⁶, R⁷ or R⁸ may be a C1-12 carbonyl group, a C1-C12 ester group, or C1-C12 ether group.

In example embodiments, the fourth repeating unit may include a structure of Formula 4-2.

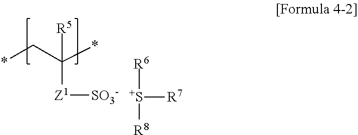

In Formula 4-2, R⁵ may is hydrogen or a methyl group; R⁶, R⁷ or R¹ may each, independently, include —C═O (a carbonyl group), —O—C═O (an ester group), —O— (an ether group), a C1 to C12 straight chain alkyl group, a C1 to C12 branched alkyl group, a C2 to C12 alkenyl group, a C2 to C12 alkynyl group, a C3 to C12 cycloalkyl group, a C6 to C12 aryl group, a C3 to C12 allyl group, a C1 to C12 alkoxy group, a C6 to C12 aryloxy group, a C7 to C20 aralkyl group, a mercaptophenyl group, or any combination thereof; Z¹ may comprise a single bond (—), ═C—, —C═C—, phenylene, phenylene fluoride, —O—, —NH, a C1 to C6 substituted or unsubstituted alkylene group, or a C6 to C12 substituted or unsubstituted cycloalkylene group, but is not limited thereto. In some embodiments, in Formula 4-2, R⁶, R⁷ or R⁸ may be a C1-12 carbonyl group, a C1-C12 ester group, or C1-C12 ether group.

In example embodiments, the fourth repeating unit may include a structure of Formula 4-3.

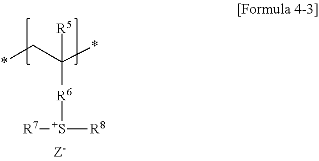

In Formula 4-3, R⁵ is hydrogen or a methyl group; R⁶ may include a single bond (—), phenylene, —O—, —NH, and R⁷ or R⁸ may include a C1 to C6 substituted or unsubstituted alkylene group or a C6 to C12 substituted or unsubstituted cycloalkylene group, but is not limited thereto. In some embodiments, in Formula 4-3, R⁷ or R⁸ may include a C1-12 carbonyl group, a C1-C12 ester group, a C1-C12 ether group, a C1 to C12 straight-chain alkyl group, a C1 to C12 branched alkyl group, a C2 to C12 alkenyl group, a C2 to C12 alkynyl group, a C3 to C12 cycloalkyl group, a C6 to C12 aryl group, an C3 to C12 allyl group, a C1 to C12 alkoxy group, a C6 to C12 aryloxy group, a C7 to C20 aralkyl group, or a mercaptophenyl group.

In example embodiments, the first photosensitive polymer may include a first repeating unit, a 2A repeating unit, a third repeating unit, and a fourth repeating unit. In example embodiments, the first photosensitive polymer may include a structure such as Structural Formula 3 but is not limited thereto. For example, the order of the first repeating unit, the 2A repeating unit, the third repeating unit, and the fourth repeating unit is not limited to the first repeating unit, the third repeating unit, the fourth repeating unit, and the 2A repeating unit as shown in Structural Formula 3, but may be arranged in various orders. In addition, a combination of the first repeating unit, the 2A repeating unit, the third repeating unit, and the fourth repeating unit is not limited to the combination of the first repeating unit, the third repeating unit, the fourth repeating unit, and the 2A repeating unit as shown in Structural Formula 3. In some embodiments, the units may be arranged in various combinations, including, for example, the first repeating unit, the first repeating unit, the third repeating unit, the fourth repeating unit, and the 2A repeating unit, but is not limited thereto.

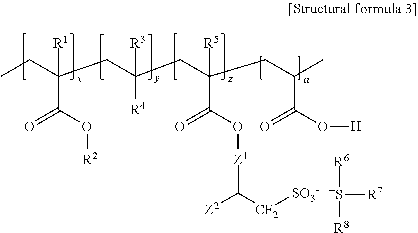

In structural Formula 3, x+y+z may be configured so that a total weight of the first repeating unit, the third repeating unit, and the fourth repeating unit relative to the weight of the first photosensitive polymer is about 90 wt % or more, and “a” may be configured so that a weight of the 2A repeating unit relative to the first photosensitive polymer is about 10 wt % or less. In some embodiments, a first photosensitive polymer comprises a first repeating unit, a third repeating unit, and a fourth repeating unit, together, in an amount of about 90% or more by weight of the first photosensitive polymer, and a 2A repeating unit in an amount of about 10% or less by weight of the first photosensitive polymer.

In the first photoresist composition according to some embodiments, the PAG may be a material that generate an acid when exposed to any light selected from among a KrF excimer laser (248 nm), an ArF excimer laser (193 nm), an F2 excimer laser (157 nm), and an EUV laser (13.5 nm). The PAG may include a material that generates a relatively strong acid with a pKa (acid dissociation constant) of about −20 to less than about 1 when exposed to light. The PAG may be an independent ionic PAG added separately to the first photoresist composition. In some embodiments, a fourth repeating unit may further be included in the first photosensitive polymer, and the PAG may further be added to the first photoresist composition, and an amount of the PAG may be adjusted as necessary. In some embodiments, adding the fourth repeating unit and/or the PAG to the first photoresist composition may allow for sufficient sensitivity.

In example embodiments, the PAG may include triarylsulfonium salts, diaryliodonium salts, sulfonates, or mixtures thereof. For example, the PAG may include triphenylsulfonium triflate, triphenylsulfonium antimonate, diphenyliodonium triflate, diphenyliodonium antimonate, methoxydiphenyliodonium triflate, di-t-butyldiphenyliodonium triflate), 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In the first photoresist composition according to embodiments, the PAG may be included in an amount of about 0.1 wt % to about 5.0 wt % based on a total weight of the photosensitive polymer, but is not limited thereto.

In example embodiments, the first photoresist composition according to the embodiments may further include a basic quencher.

The basic quencher may include a compound that traps acid generated from PAG included in the first photoresist composition according to embodiments in an unexposed region when the acid diffuses into the unexposed region of the first photoresist film. Because the basic quencher is included in the first photoresist composition according to embodiments, the diffusion rate of acid may be suppressed.

In example embodiments, the basic quencher may include a primary aliphatic amine, a secondary aliphatic amine, a tertiary aliphatic amine, an aromatic amine, a heterocyclic ring-including amine, a nitrogen-including compound having a carboxyl group, a nitrogen-including compound having a sulfonyl group, a nitrogen-including compound having a hydroxyl group, a nitrogen-including compound having a hydroxyphenyl group, an alcoholic nitrogen-including compound, amides, imides, carbamates, or ammonium salts. For example, the basic quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, Ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof, but is not limited to the above examples.

In some embodiments, the basic quencher may include a photo-decomposable base. The photo-decomposable base may include a compound that generates an acid upon exposure (e.g., upon exposure to light) and serves to neutralize the acid before exposure. When the photo-decomposable base is decomposed by exposure, it may lose its ability to trap an acid. In some embodiments, when a portion (e.g., a partial region) of the first photoresist film formed from a chemically amplified first photoresist composition including a basic quencher including a photo-decomposable base is exposed to provide an exposed region of the first photoresist film, the photo-decomposable base may lose alkalinity, and in the unexposed region of the first photoresist film, the photo-decomposable base may trap an acid. In some embodiments, the first photoresist composition including a basic quencher including the photo-decomposable base can thereby suppress the diffusion of the acid from the exposed region to the unexposed region.

The photo-decomposable base may include a carboxylate or sulfonate salt of a photo-decomposable cation. For example, the photo-decomposable cation may form a complex with an anion of a C1 to C20 carboxylic acid. The carboxylic acid may include, for example, formic acid, acetic acid, propionic acid, tartaric acid, succinic acid, cyclohexylcarboxylic acid, benzoic acid, or salicylic acid, but is not limited thereto.

In the first photoresist composition according to embodiments, the basic quencher may be included in an amount of about 0.01 wt % to about 5.0 wt % based on the total weight of the photosensitive polymer but is not limited thereto.

In the first photoresist composition according to embodiments, the first solvent may include an organic solvent. In example embodiments, the first solvent may include at least one of ether, alcohol, glycol ether, aromatic hydrocarbon compound, ketone, and ester. For example, the first solvent may be selected from among ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoic acid, methyl 3-methoxymethyl propionate, ethyl 3-methoxypropionate, ethyl 3-ethoxypropionate, methyl 3-ethoxypropionate, methyl pyruvate, ethyl pyruvate, ethyl acetate, butyl acetate, ethyl lactoate, butyl lactoate, etc. These materials may be used as the first solvent independently or in a combination of at least two of these materials. In example embodiments, the amount of the first solvent in the first photoresist composition may be adjusted so that a solid content in the first photoresist composition is in a range from about 3 wt % to about 20 wt %.

In example embodiments, the first photoresist composition according to the embodiments may further include one or more selected from a surfactant, a dispersing agent, a moisture absorbent, and/or a coupling agent.

The surfactant may serve to improve coating uniformity and wettability of the first photoresist composition. In example embodiments, the surfactant may be selected from among fluoroalkylbenzenesulfonate, fluoroalkylcarboxylate, fluoroalkylpolyoxyethylene ether, fluoroalkyl ammonium iodide, fluoroalkyl betaine, fluoroalkyl sulfonate, diglycerin tetrakis (fluoroalkyl polyoxyethylene ether), fluoroalkyl trimethyl ammonium salt, fluoroalkyl amino sulfonate, polyoxyethylene nonylphenyl ether, polyoxyethylene octylphenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene laurylamine, sorbitan laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonate, and alkyldiphenyl ether disulfonate, but is not limited thereto. The surfactant may be included in an amount in a range from about 0.001 wt % to about 3 wt % based on the total weight of the first photoresist composition, but is not limited thereto.

The dispersing agent may serve to ensure that each component constituting the first photoresist composition is uniformly dispersed within the first photoresist composition. In example embodiments, the dispersing agent may include epoxy resin, polyvinyl alcohol, polyvinyl butyral, polyvinylpyrrolidone, glucose, sodium dodecyl sulfate, sodium citrate, oleic acid, linoleic acid, or a combination thereof, but is not limited thereto. When the first photoresist composition includes the dispersing agent, the dispersing agent may be included in an amount of about 0.001 wt % to about 5 wt % based on the total weight of the first photoresist composition.

The moisture absorbent may prevent weak effects by moisture in the first photoresist composition. For example, the moisture absorbent may serve to prevent a metal included in the first photoresist composition from being oxidized by moisture. In example embodiments, the moisture absorbent may include polyoxyethylene nonylphenolether, polyethylene glycol, polypropylene glycol, polyacrylamide, or a combination thereof, but is not limited thereto. When the first photoresist composition includes the moisture absorbent, the moisture absorbent may be included in an amount of about 0.001 wt % to about 10 wt % based on the total weight of the first photoresist composition.

The coupling agent may serve to improve adhesion force between the first photoresist composition and a lower film when coating the first photoresist composition on the lower film. In example embodiments, the coupling agent may include a silane coupling agent. The silane coupling agent may include vinyltrimethoxysilane, vinyltriethoxysilane, vinyl trichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane, but is not limited thereto. When the first photoresist composition includes the coupling agent, the coupling agent may be included in an amount of about 0.001 wt % to about 5 wt % based on the total weight of the first photoresist composition.

In the first photoresist composition according to embodiments, when the first solvent includes only an organic solvent, the first photoresist composition may further include water. In this case, the water content in the first photoresist composition may be in a range from about 0.001 wt % to about 0.1 wt %.

A second photoresist composition according to some embodiments comprises a second photosensitive polymer, a photoacid generator (PAG), and a second solvent.

The composition of the second photoresist composition is generally similar to that of the first photoresist composition, but unlike the 2A repeating unit included in the first photosensitive polymer of the first photoresist composition, the second photosensitive polymer of the second photoresist composition may include a 2B repeating unit. Hereinafter, differences between the second photoresist composition and the first photoresist composition will be described.

The second photosensitive polymer may include a first repeating unit and the 2B repeating unit. A detailed description of the first repeating unit of the first photosensitive polymer has been described above and applies equally to the first repeating unit of the second photosensitive polymer, and thus, the description thereof will be omitted.

In some embodiments, the 2B repeating unit of the second photosensitive polymer may include a structure for layer by layer self-assembly. In example embodiments, the 2B repeating unit may include a structure for forming a hydrogen bond, a covalent bond, or an ionic bond such as for forming a hydrogen bond, a covalent bond, or an ionic bond with a 2A repeating unit. In example embodiments, the 2B repeating unit may include a functional group comprising oxygen for forming a hydrogen bond, a functional group comprising fluorine, a functional group comprising nitrogen, or any combination thereof. In some embodiments, the 2B repeating unit may comprise a functional group including oxygen (O), a functional group including fluorine (F), a functional group including nitrogen (N), or any combination thereof for forming a hydrogen bond.

The oxygen included in the oxygen-including functional group, the fluorine included in the fluorine-including functional group, and the nitrogen included in the nitrogen-including functional group of the 2B repeating unit may have at least one non-shared electron pair. For example, the 2B repeating unit may include a carboxyl group, an ethylene imine group, a 4-vinyl pyridine group, an ethylene oxide group, a propylene oxide group, a vinylpyrrolidone group, a 2-ethyl-2-oxazoline group, or any combination thereof. For example, the 2B repeating unit may include polycarboxylic acid, polyacrylic acid, polyethyleneimine, poly(4-vinylpyridine), poly(ethylene oxide), poly(propylene oxide), poly(vinylpyrrolidone), poly(2-ethyl-2-oxazoline), or any combination thereof.

Additionally, in example embodiments, the 2B repeating unit may include a functional group for forming a covalent bond. In example embodiments, the 2B repeating unit may include a functional group including a metal element or a non-metal element for forming an ionic bond.

The 2B repeating unit of the second photosensitive polymer may be chemically bonded to the 2A repeating unit of the first photosensitive polymer. For example, the 2B repeating unit may form a hydrogen bond, a covalent bond, or an ionic bond with the 2A repeating unit. For example, when the 2A repeating unit includes a carboxyl group and the 2B repeating unit includes an ethylene imine group, —OH of the carboxyl group of the 2A repeating unit forms a hydrogen bond with —H of the 2B repeating unit.

In example embodiments, the 2B repeating unit may include a structure selected from Formula 2-1, Formula 2-2, Formula 2-3, Formula 2-4, Formula 2-5, Formula 2-6, Formula 2-7, and any combination thereof, but is not limited thereto. The 2B repeating unit may include a structure selected from Formula 2-1, Formula 2-2, Formula 2-3, Formula 2-4, Formula 2-5, Formula 2-6, and Formula 2-7, and any combination thereof, but is not limited thereto.

In example embodiments, the 2B repeating unit of the second photosensitive polymer may include the same functional group as the 2A repeating unit of the first photosensitive polymer. For example, when the 2A repeating unit includes a carboxyl group, the 2B repeating unit may include a carboxyl group. In this case, the carboxyl group of the 2A repeating unit and the 2B repeating unit may form a carboxylic acid dimer. Alternatively, in example embodiments, the 2B repeating unit of the second photosensitive polymer may include a different functional group from the 2A repeating unit of the first photosensitive polymer. For example, when the 2A repeating unit includes a carboxyl group, the 2B repeating unit includes an ethylene imine group, a 4-vinyl pyridine group, an ethylene oxide group, a propylene oxide group, a vinylpyrrolidone group, a 2-ethyl-2-oxazoline, or any combination thereof.

In example embodiments, the second photosensitive polymer may further include a third repeating unit. The third repeating unit may be decomposed by an action of an acid to generate phenolic acid or a Bronsted acid corresponding to the phenolic acid. In example embodiments, the third repeating unit may include a structure obtained from hydroxystyrene or a derivative thereof.

The hydroxystyrene derivative may include those in which a hydrogen atom at the a position of hydroxystyrene is substituted with a C1 to C5 alkyl group or a C1 to C5 halogenated alkyl group, and a derivative thereof. In example embodiments, the third repeating unit may include a structure obtained from methoxycystyrene or a derivative thereof. A detailed description of the third repeating unit of the second photosensitive polymer is the same as the description of the third repeating unit of the first photosensitive polymer, and thus, the description thereof is omitted.

In example embodiments, the second photosensitive polymer may further include a fourth repeating unit. The second photosensitive polymer and/or the fourth repeating unit of the second photosensitive polymer may include a material that generates an acid when exposed to a light selected from a KrF excimer laser (248 nm), an ArF excimer laser (193 nm), an F2 excimer laser (157 nm), and an EUV laser (13.5 nm). The fourth repeating unit may include a material that generates a relatively strong acid having a pKa (acid dissociation constant) of about −20 or more and less than about 1 when exposed to light. In some example embodiments, the fourth repeating unit may include a photo-decomposable base. The photo-decomposable base may include a compound that generates acid upon exposure and serves to neutralize the acid before exposure. When the photo-decomposable base is decomposed by exposure, it may lose its ability to trap an acid. A detailed description of the fourth repeating unit of the first photosensitive polymer has been described above and applies equally to the fourth repeating unit of the second photosensitive polymer, and thus, the description of the fourth repeating unit of the second photosensitive polymer is omitted.

In the second photoresist composition according to the embodiments, the PAG may be a material that generates an acid when exposed to light selected from a KrF excimer laser (248 nm), an ArF excimer laser (193 nm), an F2 excimer laser (157 nm), and an EUV laser (13.5 nm). The PAG may include a material that generates a relatively strong acid having a pKa (acid dissociation constant) of about −20 or more and less than about 1 when exposed to light.

In example embodiments, the PAG of the second photoresist composition may include one or more material(s) illustrated as constituting the PAG in the description of the first photoresist composition. In the second photoresist composition, the PAG may be included in an amount of about 0.1 wt % to about 5.0 wt % based on the total weight of the second photosensitive polymer, but is not limited thereto. The PAG may be an independent ionic PAG added separately into the second photoresist composition. In some embodiments, the fourth repeating unit may be further included in the second photosensitive polymer, and the PAG may further be added to the second photoresist composition, and the amount thereof may be adjusted as necessary. In some embodiments, including the fourth repeating unit and/or the PAG to the second photoresist composition may allow for sufficient sensitivity.

In example embodiments, the second photoresist composition according to the inventive concept may further include a basic quencher. The basic quencher may include a compound that may trap an acid generated from the PAG included in the second photoresist composition according to embodiments in an unexposed region when the acid diffuses into the unexposed region of the second photoresist film. Because the basic quencher is included in the second photoresist composition according to embodiments, the diffusion rate of acid may be suppressed.

In example embodiments, the basic quencher of a second photoresist composition may include materials illustrated as constituting the basic quencher in the description of the first photoresist composition. In the second photoresist composition according to embodiments, the basic quencher may be included in an amount in a range from about 0.01 wt % to about 5.0 wt % based on the total weight of the second photosensitive polymer, but is not limited thereto.

In the second photoresist composition according to embodiments, the second solvent may be an organic solvent. In example embodiments, the second solvent may include materials illustrated as constituting the second solvent in the description of the first photoresist composition.

The second solvent may be used alone or in combination of at least two kinds. In example embodiments, the amount of the second solvent in the second photoresist composition may be adjusted so that a solid content in the second photoresist composition is in a range from about 3 wt % to about 20 wt %.

In example embodiments, the second photoresist composition according to embodiments may further include a surfactant, a dispersing agent, a moisture absorbent, and/or a coupling agent.

In example embodiments, a surfactant, a dispersing agent, a moisture absorbent, and/or a coupling agent of a second photoresist composition may include materials illustrated as constituting a surfactant, a dispersing agent, a moisture absorbent, and a coupling agent, respectively, in the description for a first photoresist composition, but are not limited thereto.

The surfactant may be included in an amount in a range from about 0.001 wt % to about 3 wt % based on the total weight of the second photoresist composition, the dispersing agent may be included in an amount in a range from about 0.001 wt % to about 5 wt % based on the total weight of the second photoresist composition, the moisture absorbent may be included in an amount in a range from about 0.001 wt % to about 10 wt % based on the total weight of the second photoresist composition, and/or the coupling agent may be included in an amount in a range from about 0.001 wt % to about 5 wt % based on the total weight of the second photoresist composition.

In the second photoresist composition according to embodiments, when the second solvent includes only an organic solvent, the second photoresist composition may further include water.

In this case, the water content in the second photoresist composition may be in a range from about 0.001 wt % to about 0.1 wt %.

Hereinafter, a structure of the photoresist film formed by using the above-described first and second photoresist compositions will be described in detail.

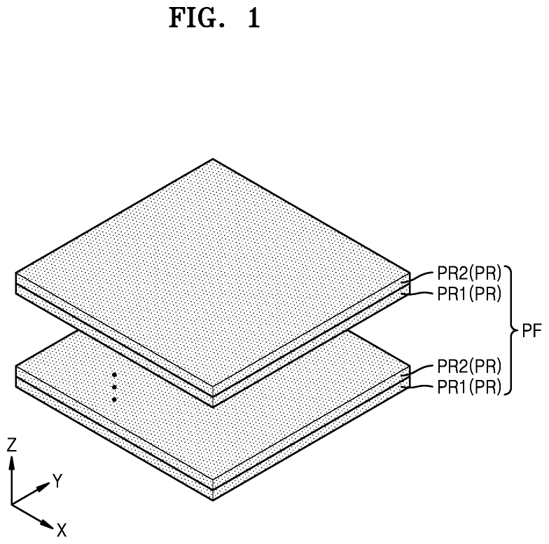

FIG. 1 is a perspective view for explaining a structure of a photoresist film PF according to embodiments.

Referring to FIG. 1, the photoresist film PF may include a plurality of photoresist layers PRs. In example embodiments, the photoresist film PF may include a first photoresist layer PR1 and a second photoresist layer PR2 that is on the first photoresist layer PR1.

In example embodiments, the plurality of photoresist layers PRs may have different chemical compositions from each other. For example, the chemical composition of the first photoresist layer PR1 and the chemical composition of the second photoresist layer PR2 may be different from each other.

In example embodiments, the photoresist layer PR including the first photosensitive polymer described above may be referred to as the first photoresist layer PR1, and the photoresist layer PR including the second photosensitive polymer may be referred to as the second photoresist layer PR2. The second photoresist layer PR2 may be disposed at a different level in the vertical direction Z from the first photoresist layer PR1. Accordingly, the second photoresist layer PR2 may be disposed at two or more different positions in a direction perpendicular to a surface of the first photoresist layer PR1 (e.g., a surface extending in the horizontal direction). The second photosensitive polymer may form a hydrogen bond, a covalent bond, or an ionic bond with the first photosensitive polymer.

The first photosensitive polymer may include the first repeating unit described above and the 2A repeating unit described above, and the second photosensitive polymer may include the first repeating unit described above and the 2B repeating unit described above. The 2B repeating unit may form a hydrogen bond, a covalent bond, or an ionic bond with the 2A repeating unit.

As described above, the 2A repeating unit or the 2B repeating unit may include a carboxyl group, an ethylene imine group, a 4-vinylpyridine group, an ethylene oxide group, a propylene oxide group, a vinylpyrrolidone group, a 2-ethyl-2-oxazoline group, or any combination thereof.

For example, the 2A repeating unit may include a carboxyl group, and the 2B repeating unit may include an ethylene imine group, a 4-vinylpyridine group, an ethylene oxide group, a propylene oxide group, a vinylpyrrolidone group, a 2-ethyl-2-oxazoline group, or any combination thereof.

For example, the 2A repeating unit or the 2B repeating unit may include a structure selected from Formula 2-1, Formula 2-2, Formula 2-3, Formula 2-4, Formula 2-5, Formula 2-6, and Formula 2-7 as described above.

The first photosensitive polymer and/or the second photosensitive polymer may further include a third repeating unit represented by Chemical Formula 3 as described above. In addition, the first photosensitive polymer and/or the second photosensitive polymer may further include the fourth repeating unit as described above, and the fourth repeating unit may include a material that generates an acid when exposed to a light selected from a KrF excimer laser (248 nm), an ArF excimer laser (193 nm), an F2 excimer laser (157 nm), and an EUV laser (13.5 nm), or may include a photo-decomposable base.

The first photoresist layer PR1 or the second photoresist layer PR2 may further include a basic quencher.

The first photosensitive polymer of the first photoresist layer PR1 and the second photosensitive polymer of the second photoresist layer PR2 may be different. For example, the first photosensitive polymer of the first photoresist layer PR1 may include the first repeating unit, the 2A repeating unit, and the third repeating unit, and the second photosensitive polymer of the second photoresist layer PR2 may include the first repeating unit, the 2A repeating unit, the third repeating unit, and the fourth repeating unit.

In example embodiments, the 2A repeating unit included in the first photosensitive polymer of the first photoresist layer PR1 and the 2B repeating unit included in the second photosensitive polymer of the second photoresist layer PR2 may include functional groups different from each other. For example, the 2A repeating unit included in the first photosensitive polymer may include polycarboxylic acid, and the 2B repeating unit included in the second photosensitive polymer may include polyethyleneimine.

As shown if FIG. 1, the photoresist film PF may include a first photoresist layer PR1 and a second photoresist layer PR2 having different chemical compositions, but is not limited thereto, and may include two or more photoresist layers PR having different chemical compositions. For example, the photoresist film PF may include the first photoresist layer PR1, the second photoresist layer PR2, and a third photoresist layer having different chemical compositions.

According to the inventive concept, because the photoresist film PF includes a plurality of photoresist layers PRs, each of the plurality of photoresist layers PRs may be configured to have chemical compositions different from each other. Therefore, unlike a photoresist film having a single-layer structure, in the photoresist film PF having a multi-layered structure, because the chemical compositions of the plurality of photoresist layers PR may be controlled to be different from each other, the chemical compositions of the plurality of photoresist layers PR may be configured layer by layer in various ways.

In addition, when a single-layer photoresist film is formed using a single photosensitive polymer including a long repeating group, entanglement of the photosensitive polymer may occur, resulting in deterioration of the photoresist pattern. However, when a multi-layered photoresist film is formed using a plurality of photosensitive polymers including repeating groups having a relatively short length but having different chemical compositions according to embodiments, entanglement of the photosensitive polymers may be minimized, thereby preventing deterioration of the photoresist pattern. Ultimately, when performing a photolithography process for manufacturing an integrated circuit device, light sensitivity may be increased, and the resolution of the photoresist film may be improved.

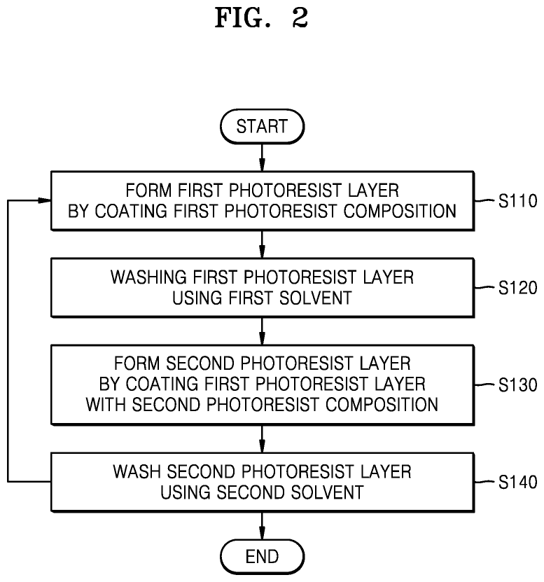

FIG. 2 is a flow chart for explaining a method of manufacturing a photoresist film according to some embodiments.

Referring to FIG. 2, the method of manufacturing a photoresist film PF according to some embodiments may include forming a first photoresist layer by coating a first photoresist composition (S110), washing the first photoresist layer using a first solvent (S120), forming a second photoresist layer by coating a second photoresist composition on the first photoresist layer (S130), and washing the second photoresist layer using a second solvent (S140).

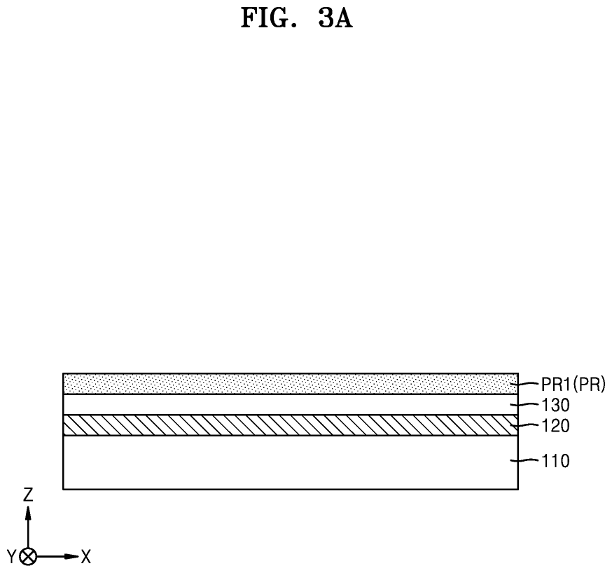

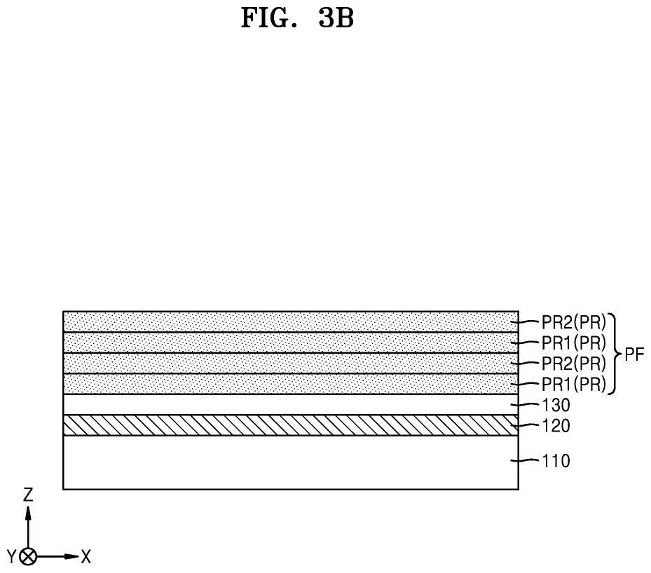

FIGS. 3A and 3B are cross-sectional views for illustrating aspects of a method of manufacturing a photoresist film according to some embodiments. The manufacturing method of the photoresist film illustrated in FIG. 2 is described in more detail with reference to FIGS. 3A and 3B.

Referring to FIG. 3A, the first photoresist layer PR1 may be formed by coating a first photoresist composition according to some embodiments (S110 of FIG. 2). To form the first photoresist layer PR1, a substrate 110 including a feature layer 120 may be provided. The feature layer 120 may be formed on the substrate 110. The first photoresist layer PR1 may be formed on the feature layer 120. The first photoresist layer PR1 may include a first photosensitive polymer, which is a component of the first photoresist composition described above, a PAG, and a solvent.

The first photosensitive polymer may include a functional group capable of forming (e.g., configured to form and/or that can form) a hydrogen bond, a covalent bond, or an ionic bond. A more detailed structure of the first photoresist composition is as described above.

The substrate 110 may include a semiconductor substrate. The feature layer 120 may include an insulating film, a conductive film, or a semiconductor film. For example, the feature layer 120 may include a metal, an alloy, a metal carbide, a metal nitride, a metal oxynitride, a metal oxycarbide, a semiconductor, polysilicon, an oxide, a nitride, an oxynitride, or any combination thereof, but is not limited thereto.

In example embodiments, as illustrated in FIG. 3A, before forming the first photoresist layer PR1 on the feature layer 120, a developable bottom anti-reflective coating (DBARC) film 130 may be formed on the feature layer 120. In this case, the first photoresist layer PR1 may be formed on the DBARC film 130. The DBARC film 130 may control diffuse reflection of light from a light source used during an exposure process for manufacturing an integrated circuit device or may serve to absorb reflected light from the lower feature layer 120. In example embodiments, the DBARC film 130 may include an organic anti-reflective coating (ARC) material for a KrF excimer laser, an ArF excimer laser, or any other light source. In example embodiments, the DBARC film 130 may include an organic component having a light absorption structure. The light absorption structure may be, for example, a hydrocarbon compound having at least benzene ring or a structure in which benzene rings are fused. The DBARC film 130 may be formed to have a thickness in a range from about 20 nm to about 100 nm, but is not limited thereto. In example embodiments, the DBARC membrane 130 may be omitted.

To form the first photoresist layer PR1, a first photoresist composition may be coated on the DBARC film 130. If the DBARC film 130 is omitted, the first photoresist composition may be coated on the feature layer 120. The coating may be performed by methods such as a spin coating method, a spray coating method, and a deep coating method. After coating the first photoresist composition on the feature layer 120, a heat treatment process may be performed. The process of heat treating the first photoresist composition may be performed at a temperature in a range from about 80° C. to about 300° C. for about 10 seconds to about 100 seconds, but is not limited thereto. A thickness of the first photoresist layer PR1 may be tens to hundreds of times the thickness of the DBARC film 130. The first photoresist layer PR1 may be formed to have a thickness in a range from about 100 nm to about 6 m, but is not limited thereto.

After coating the first photoresist composition to form the first photoresist layer PR1, the first photoresist layer (PR1) may be washed using a first solvent (S120 in FIG. 2). By the washing, a portion of the first photoresist composition that has not formed the first photoresist layer PR1 may be removed. The washing may be performed by a method such as a spin washing method, but is not limited thereto. Depending on the processing method, the washing may be omitted.

Referring to FIG. 3B, a second photoresist layer PR2 may be formed by coating a second photoresist composition on the first photoresist layer PR1 according to embodiments (S130 of FIG. 2).

The second photoresist layer PR2 may be formed on the first photoresist layer PR1 to be disposed at different levels in a vertical direction to the first photoresist layer PR1. The second photoresist layer PR2 may include a second photosensitive polymer, which is a component of the second photoresist composition described above, a PAG, and a second solvent. The second photosensitive polymer may form a hydrogen bond, a covalent bond, or an ionic bond with the first photosensitive polymer of the first photoresist layer PR1. A more detailed structure of the second photoresist composition is as described above.

To form the second photoresist layer PR2, the second photoresist composition described above may be coated on the first photoresist layer PR1. The coating may be performed by methods such as a spin coating method, a spray coating method, and a deep coating method. After coating the second photoresist composition on the first photoresist layer PR1, a heat treatment process may be performed. The process of heat treating the second photoresist composition may be performed at a temperature in a range from about 80° C. to about 300° C. for about 10 seconds to about 100 seconds, but is not limited thereto. A thickness of the second photoresist layer PR2 may be tens to hundreds of times the thickness of the DBARC film 130. The second photoresist layer PR2 may be formed to have a thickness in a range from about 100 nm to about 6 m, but is not limited thereto.

After coating the second photoresist composition to form the second photoresist layer PR2, the second photoresist layer (PR2) may be washed using a second solvent (S140 in FIG. 2). By the washing, a portion of the second photoresist composition that has not formed the second photoresist layer PR2 may be removed. The washing may be performed by a method such as a spin washing method, but is not limited thereto. Depending on the processing method, the washing may be omitted.

After forming the second photoresist layer PR2, the process of forming a first photoresist layer PR1 on the second photoresist layer PR2 may be performed at a different level in a direction perpendicular to the second photoresist layer PR2 and forming a second photoresist layer PR2 on the first photoresist layer PR1 may be repeatedly performed. The process of forming the first photoresist layer PR1 and the second photoresist layer PR2 may be repeatedly performed until a target thickness of the photoresist film PF is reached.

The number of photoresist layers PR constituting the photoresist film PF is not limited to that shown in FIG. 3B and may include two or more photoresist layers PR having different chemical compositions. For example, a third photoresist layer (not shown) having a chemical composition different from the first photoresist layer PR1 and the second photoresist layer PR2 may be formed on the second photoresist layer PR2. The process of forming the third photoresist layer (not shown) may be similar to the process of forming the second photoresist layer PR2.

According to the inventive concept, a photoresist film PF is formed by sequentially stacking a plurality of photoresist layers PRs (e.g., sequentially stacking a first photoresist layer and a second photoresist layer two or more times), the chemical composition of each of the plurality of photoresist layers PR may be configured to be different from each other. Therefore, unlike a photoresist film having a single-layer structure, in the photoresist film PF having a multi-layered structure, because the chemical composition of each of the plurality of photoresist layers PR may be controlled to be different from each other, the chemical composition of the plurality of photoresist layers PR may be configured layer by layer in various ways.

In addition, when a single-layer photoresist film is formed using a single photosensitive polymer including a long repeating group, entanglement of the photosensitive polymer may occur resulting in deterioration of the photoresist pattern. However, when forming a multi-layered photoresist film using a plurality of photosensitive polymers including repeating groups having a relatively short length but having different chemical compositions according to embodiments, entanglement of the photosensitive polymers may be minimized, thereby preventing deterioration of the photoresist pattern. Ultimately, when performing a photolithography process for manufacturing an integrated circuit device, light sensitivity may be increased, and the resolution of the photoresist film may be improved.

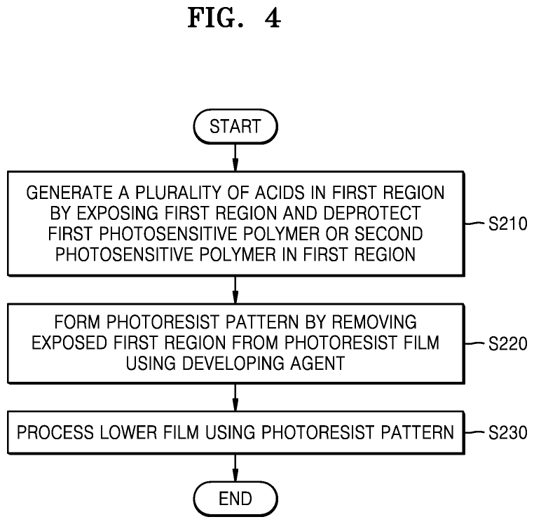

FIG. 4 is a flow chart for explaining a method of manufacturing an integrated circuit device according to some embodiments.

Referring to FIG. 4, a method of manufacturing an integrated circuit device according to some embodiments may include exposing a first region of the photoresist film to deprotect the first repeating unit in the first region to separate an acid-decomposable protecting group (e.g., an acid labile protecting group) and generate a sensitizer from the first repeating unit (S210), forming a photoresist pattern by removing the exposed first region from the photoresist film using a developing agent (S220), and processing a lower film using the photoresist pattern (S230). The processing of the lower film using the photoresist pattern (S230) may include processing a feature layer using the photoresist pattern and removing the photoresist pattern and a DBARC pattern remaining on the processed feature layer.

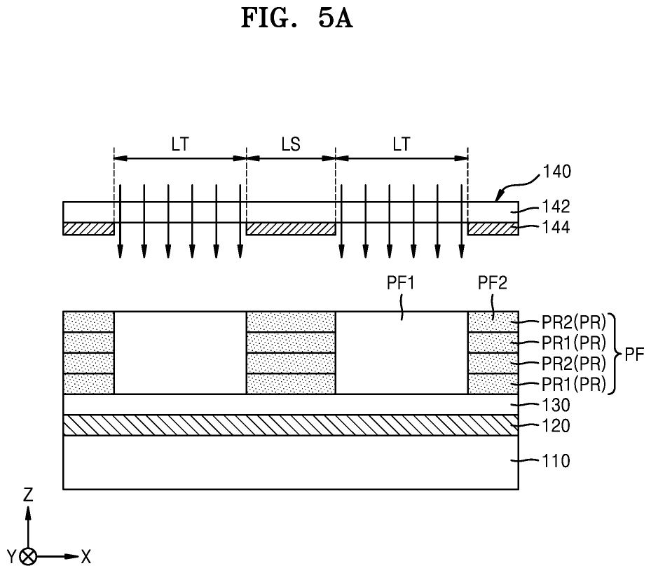

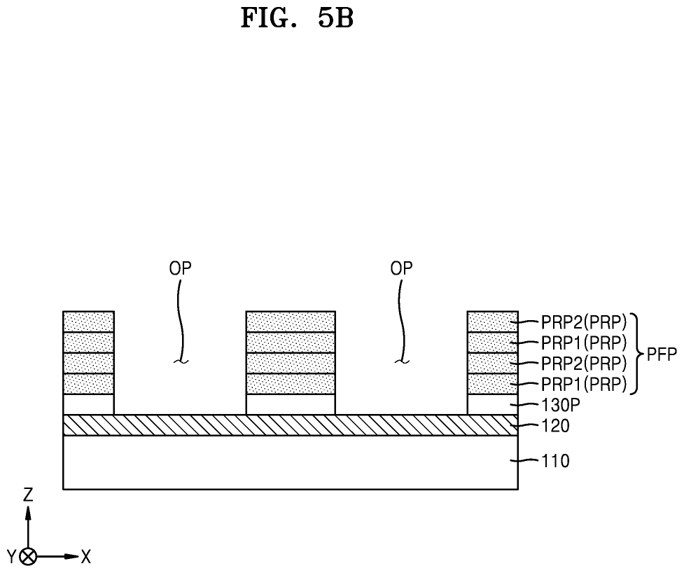

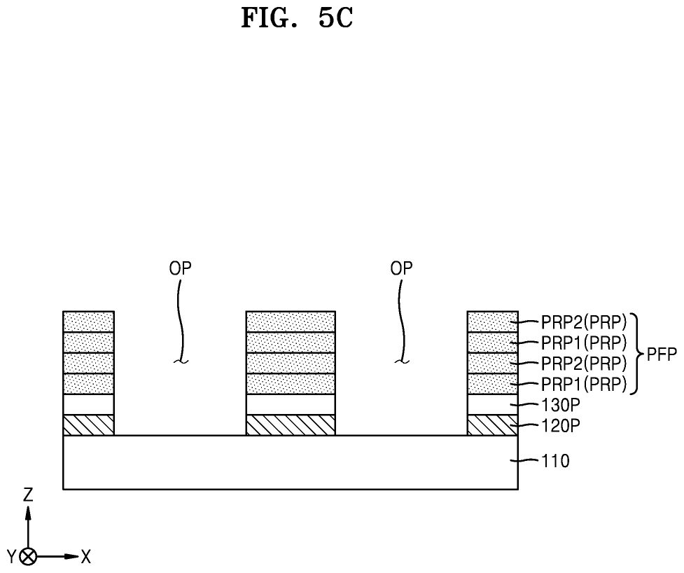

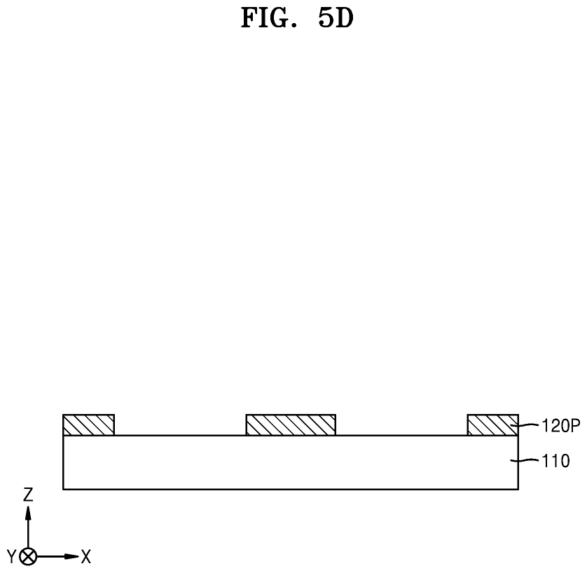

FIGS. 5A to 5D are cross-sectional views for illustrating aspects of a method of manufacturing an integrated circuit device according to some embodiments. The manufacturing method of the integrated circuit device illustrated in FIG. 4 will be described in more detail with reference to FIGS. 5A to 5D.

Referring to FIG. 5A, the first region PF1 of the photoresist film PF, such as described in FIG. 3B, is exposed to deprotect the first repeating unit in the first region so that the acid-decomposable protecting group (e.g., an acid labile protecting group) is separated, and as a result, a sensitizer may be generated from the first repeating unit (S210 in FIG. 4).

To expose the first region PF1 of the photoresist film PF, a KrF excimer laser (248 nm), an ArF excimer laser (193 nm), an F2 excimer laser (157 nm), or an EUV laser (13.5 nm) may be used.

In example embodiments, the photoresist film PF includes the first photosensitive polymer described above or the second photosensitive polymer described above, when the first region PF1 of the photoresist film PF is exposed, an acid is generated from a PAG in the first region PF1, and by the acid generated from the PAG, the first repeating unit having the acid-decomposable protecting group (e.g., an acid labile protecting group) indicated by R² described above of the first photosensitive polymer or the second photosensitive polymer may be deprotected and the acid-decomposable protecting group may be separated.

In example embodiments, when the first photosensitive polymer described above or the second photosensitive polymer described above further includes the third repeating unit described above, then when the first region PF1 of the photoresist film PF is exposed, an acid is generated from the PAG in the first region PF1, and by the acid generated from the PAG, the third repeating unit having the acid-decomposable protecting group (e.g., an acid labile protecting group) indicated by R⁴ described above of the first or second photosensitive polymer may be deprotected and the acid-decomposable protecting group may be separated.

In example embodiments, when the first photosensitive polymer described above or the second photosensitive polymer described above further includes the fourth repeating unit described above, then when the first region PF1 of the photoresist film PF is exposed, an acid is generated from the fourth repeating unit in the first region PF1, and by the acid generated from the fourth repeating unit, the first repeating unit having the acid-decomposable protecting group indicated by R² described above of the first or second photosensitive polymer may be deprotected and the acid-decomposable protecting group may be separated. In example embodiments, when the first photosensitive polymer described above or the second photosensitive polymer described above further includes the third repeating unit described above and the fourth repeating unit described above, by an acid generated from the fourth repeating unit, the third repeating unit having the acid-decomposable protecting group indicated by R⁴ described above of the first photosensitive polymer or the second photosensitive polymer may be deprotected and the acid-decomposable protecting group may be separated. Accordingly, when developing the photoresist film PF in a subsequent process, the first region PF1 may have high solubility in the developing agent.

In the second region PF2, which is an unexposed region of the photoresist film PF, the structure in which the first repeating unit includes an acid-decomposable protecting group (e.g., an acid labile protecting group) may be maintained as it is. Therefore, when developing the photoresist film PF in a subsequent process, the second region PF2 may have low solubility in the developing agent. Accordingly, the solubility of the exposed first region PF1 and the unexposed second region 134 of the photoresist film PF in the developing agent may be different.

In example embodiments, to expose the first region PF1 of the photoresist film PF, a photomask 140 having a plurality of light shielding regions LS and a plurality of light transmitting regions LT is aligned at a predetermined position on the photoresist film PF, and the first region PF1 of the photoresist film PF may be exposed through the plurality of light transmitting regions LT of the photomask 140. To expose the first region PF1 of the photoresist film PF, a KrF excimer laser (248 nm), an ArF excimer laser (193 nm), an F2 excimer laser (157 nm), or an EUV laser (13.5 nm) may be used.

The photomask 140 may include a transparent substrate 142 and a plurality of light shielding patterns 144 formed in the plurality of light shielding regions LS on the transparent substrate 142. The transparent substrate 142 may include quartz. The plurality of light shielding patterns 144 may include chrome (Cr). The plurality of light transmitting regions LT may be defined by the plurality of light shielding patterns 144. According to the technical idea of the inventive concept, to expose the first region PF1 of the photoresist film PF, a reflective photomask (not shown) for EUV exposure may be used instead of the photomask 140. Hereinafter, a transmissive photomask is mainly described, but those skilled in the art may understand that exposure may be performed by using an equivalent configuration of a reflective photomask as well.

After exposing the first region PF1 of the photoresist film PF, the photoresist film PF may be annealed. The annealing may be performed at a temperature in a range from about 50° C. to about 200° C. for about 10 seconds to about 100 seconds, but is not limited thereto.

Referring to FIG. 5B, the exposed first region PF1 may be removed from the photoresist film PF using a developing agent to form a photoresist pattern PFP. As a result, the photoresist pattern PFP including the unexposed second region PF2 may be formed (S220 in FIG. 4).

The photoresist pattern PFP may include a plurality of openings OP. After the photoresist pattern PFP is formed, a DBARC pattern 130P may be formed by removing a portion of the DBARC film 130 exposed through the plurality of openings OP.

In example embodiments, a developing agent may be used to develop the photoresist film PF. The developing agent may include a 2.38 wt % tetramethylammonium hydroxide (TMAH) solution. Alternatively, n-butyl acetate (nBA) or 2-heptanone may be used as the developing agent, but the type of developing agent is not limited thereto.

In the first region PF1 of the photoresist film PF, the first repeating unit including an acid-decomposable protecting group (e.g., an acid labile protecting group) is deprotected from the first or second photosensitive polymer and the acid-decomposable protecting group is separated. Thus, the first region PF1 may have high solubility in the developing agent. On the other hand, in the second region PF2 of the photoresist film PF, the first repeating unit is not deprotected and the acid-decomposable protecting group is not separated; thus, the solubility in the developing agent may be low. Accordingly, while developing the photoresist film PF with the developing agent, the first region PF1 may be removed and the second region PF2 may remain.

Referring to FIG. 5C, the feature layer 120 may be processed using a photoresist pattern PFP in the result of FIG. 5B (S230 in FIG. 4).

In order to process the feature layer 120, various processes may be performed, such as a process of etching the feature layer 120 exposed through an opening OP of the photoresist pattern PFP, a process of implanting impurity ions into the feature layer 120, a process of forming an additional film on the feature layer 120 through the opening OP, and a process of deforming a portion of the feature layer 120 through the opening OP. In FIG. 5C, as an example process for processing the feature layer 120, a case in which the feature layer 120 exposed through the opening OP is etched to form the feature pattern 120P is illustrated.

In other example embodiments, the process of forming the feature layer 120 may be omitted in the process described with reference to FIG. 3A, and in this case, the substrate 110 may be processed using the photoresist pattern PFP. For example, various processes may be performed, such as a process of etching a portion of the substrate 110 using the photoresist pattern PFP, a process of implanting impurity ions into a partial region of the substrate 110, a process of forming an additional film on the substrate 110 through the opening OP, and a process of deforming a part of the substrate 110 through the opening OP.

Referring to FIG. 5D, a process of removing the photoresist pattern PFP and the DBARC pattern 130P remaining on the feature pattern 120P may be performed to the resultant product of FIG. 5C. Ashing and strip processes may be used to remove the photoresist pattern PFP and the DBARC pattern 130P.

While the inventive concept has been particularly shown and described with reference to embodiments thereof, it will be understood that various changes in form and details may be made therein without departing from the spirit and scope of the following claims.

What is claimed is:

1. A photoresist film comprising:
a first photoresist layer including a first photosensitive polymer; and
a second photoresist layer including a second photosensitive polymer,
wherein the second photoresist layer is disposed at two or more different positions in a direction perpendicular to a surface of the first photoresist layer, and
wherein the second photosensitive polymer is hydrogen bonded, covalently bonded, or ionically bond to the first photosensitive polymer.

2. The photoresist film of claim 1, wherein the first photosensitive polymer includes:
a first repeating unit according to Formula 1; and
a 2A repeating unit; and
wherein the second photosensitive polymer includes:
the first repeating unit according to Formula 1; and
a 2B repeating unit that is hydrogen bonded, covalently bonded, or ionically bonded to the 2A repeating unit, 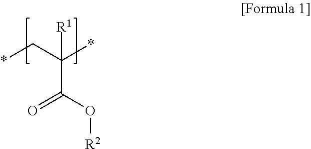
wherein:
R¹ is hydrogen or a methyl group,
R² is an acid labile protecting group, and
* is a binding site.

3. The photoresist film of claim 2, wherein the 2A repeating unit and/or the 2B repeating unit includes a carboxyl group, an ethylene imine group, a 4-vinylpyridine group, an ethylene oxide group, a propylene oxide group, a vinylpyrrolidone group, a 2-ethyl-2-oxazoline group, or any combination thereof.

4. The photoresist film of claim 2, wherein the 2A repeating unit includes a carboxyl group, and the 2B repeating unit includes an ethylene imine group, a 4-vinylpyridine group, an ethylene oxide group, a propylene oxide group, a vinylpyrrolidone group, a 2-ethyl-2-oxazoline group, or any combination thereof.

5. The photoresist film of claim 2, wherein the 2A repeating unit or the 2B repeating unit includes a structure according to Formula 2-1, Formula 2-2, Formula 2-3, Formula 2-4, Formula 2-5, Formula 2-6, Formula 2-7, or any combination thereof: 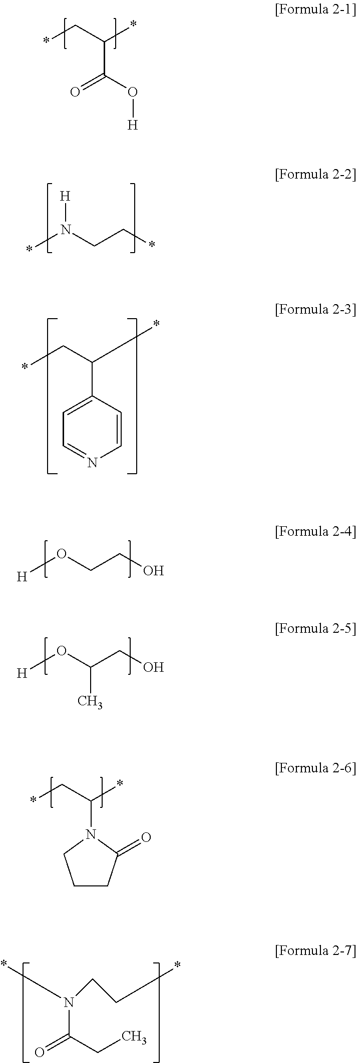
wherein, in Formula 2-1, Formula 2-2, Formula 2-3, Formula 2-4, Formula 2-5, Formula 2-6, and Formula 2-7, * is a binding site.

6. The photoresist film of claim 2, wherein the first photosensitive polymer and/or the second photosensitive polymer further includes a third repeating unit according to Formula 3: 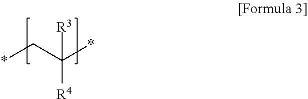
wherein:
R³ is a hydrogen atom or a methyl group,
R⁴ is a C6-C30 aryl group including at least one hydroxy group or at least one methoxy group, and
* is a binding site.

7. The photoresist film of claim 6, wherein R⁴ further includes an acid-decomposable protecting group.

8. The photoresist film of claim 2, wherein
the first photosensitive polymer and/or the second photosensitive polymer includes a material that generates an acid when exposed to a light selected from a KrF excimer laser (248 nm), an ArF excimer laser (193 nm), an F2 excimer laser (157 nm), and an EUV laser (13.5 nm), or the first photosensitive polymer and/or the second photosensitive polymer further includes a fourth repeating unit including a photo-decomposable base.

9. A photoresist film comprising:
a first photoresist layer including a first photosensitive polymer; and
a second photoresist layer including a second photosensitive polymer,
wherein the second photoresist layer is disposed at two or more different positions in a direction perpendicular to a surface of the first photoresist layer, and
wherein the first photoresist layer has a different chemical composition than the second photoresist layer.

10. The photoresist film of claim 9, wherein the first photosensitive polymer is different than the second photosensitive polymer.

11. The photoresist film of claim 9, wherein the first photoresist layer and/or the second photoresist layer further includes a basic quencher.

12. A method of manufacturing an integrated circuit device, the method comprising:
providing a substrate including a feature layer; and
forming a photoresist film on the feature layer,
wherein the forming of the photoresist film includes:
forming a first photoresist layer by coating a first photoresist composition including a first photosensitive polymer on the feature layer;
forming a second photoresist layer by coating the first photoresist layer with a second photoresist composition including a second photosensitive polymer; and
repeating the forming of the first photoresist layer and the forming of the second photoresist layer until a target thickness of the photoresist film is reached, thereby providing the second photoresist layer at two or more different positions in a direction perpendicular to a surface of the first photoresist layer, and
wherein, in forming the second photoresist layer, the second photosensitive polymer forms a hydrogen bond, a covalent bond, or an ionic bond with the first photosensitive polymer.

13. The method of claim 12, further comprising,
after forming the first photoresist layer, washing the first photoresist layer using a first solvent of the first photoresist composition.

14. The method of claim 12, further comprising,
after forming the photoresist film,
generating a plurality of acids in a first region of the photoresist film by exposing the first region to provide an exposed first region and deprotecting the first photosensitive polymer and/or the second photosensitive polymer in the first region;
forming a photoresist pattern comprising an unexposed second region of the photoresist film by removing the exposed first region of the photoresist film using a developing agent; and
processing the feature layer using the photoresist pattern.

15. The method of claim 12, wherein the first photosensitive polymer includes:
a first repeating unit according to Formula 1; and
a 2A repeating unit, and
wherein the second photosensitive polymer includes:
the first repeating unit according to Formula 1; and
a 2B repeating unit that forms a hydrogen bond, a covalent bond, or an ionic bond with the 2A repeating unit, 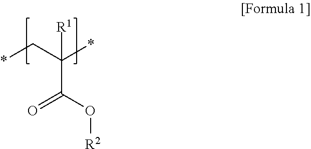
wherein, in Formula 1, R¹ is hydrogen or a methyl group; R² is an acid labile protecting group; and * is a binding site.

16. The method of claim 15, wherein the 2A repeating unit and/or the 2B repeating unit includes a carboxyl group, an ethylene imine group, a 4-vinylpyridine group, an ethylene oxide group, a propylene oxide group, a vinylpyrrolidone group, a 2-ethyl-2-oxazoline group, or any combination thereof.

17. The method of claim 15, wherein the 2A repeating unit includes a carboxyl group, and the 2B repeating unit includes an ethylene imine group, a 4-vinylpyridine group, an ethylene oxide group, a propylene oxide group, a vinylpyrrolidone group, a 2-ethyl-2-oxazoline group, or any combination thereof.

18. The method of claim 15, wherein the 2A repeating unit and/or the 2B repeating unit includes a structure according to Formula 2-1, Formula 2-2, Formula 2-3, Formula 2-4, Formula 2-5, Formula 2-6, Formula 2-7, or any combination thereof: 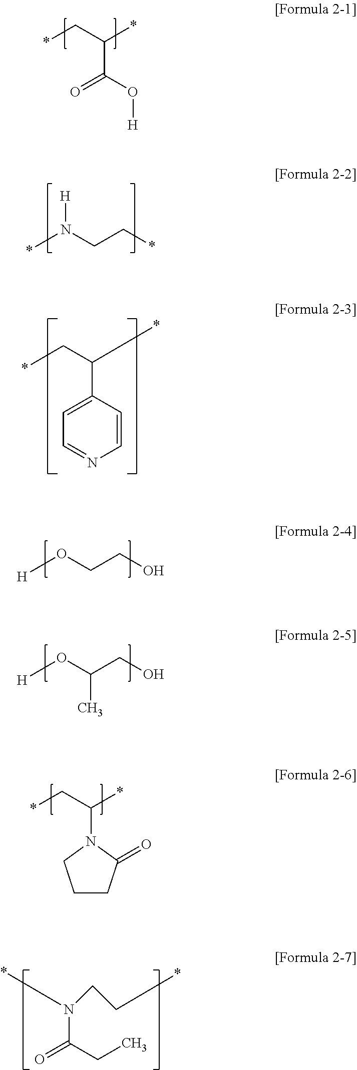
wherein, in Formula 2-1, Formula 2-2, Formula 2-3, Formula 2-4, Formula 2-5, Formula 2-6, and Formula 2-7, * is a binding site.

19. The method of claim 15, wherein the first photosensitive polymer or the second photosensitive polymer further includes a third repeating unit represented by Formula 3: 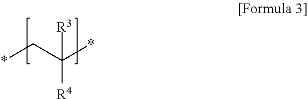
wherein:
R³ is a hydrogen atom or a methyl group,
R⁴ is a C6-C30 aryl group including at least one hydroxy group or at least one methoxy group, and
* is a binding site.

20. The method of claim 15, wherein
the first photosensitive polymer or the second photosensitive polymer includes a material that generates an acid when exposed to a light selected from a KrF excimer laser (248 nm), an ArF excimer laser (193 nm), an F2 excimer laser (157 nm), and an EUV laser (13.5 nm), or the first photosensitive polymer or the second photosensitive polymer further includes a fourth repeating unit including a photo-decomposable base.
